(19) United States
(12) Patent Application Publication
(10) Pub. No.: US 2014/0246065 A1
(43) Pub. Date: Sep. 4, 2014

(54) METHOD FOR ENHANCEMENT OF THERMOELECTRIC EFFICIENCY BY THE PREPARATION OF NANO THERMOELECTRIC POWDER WITH CORE-SHELL STRUCTURE

(71) Applicant: Jong Min Lee, Seoul (KR)

(72) Inventor: Jong Min Lee, Seoul (KR)

(73) Assignee: LG INNOTEK CO., LTD., Seoul (KR)

(21) Appl. No.: 14/348,691

(22) PCT Filed: Sep. 28, 2012
(86) PCT No.: PCT/KR2012/007928

§ 371 Date: Mar. 31, 2014

(30) Foreign Application Priority Data
Sep. 29, 2011 (KR) 10-2011-0099210

(51) Int. Cl. H01L 35/26; H01L 35/34

(52) U.S. Cl. CPC H01L 35/26; H01L 35/34
USPC 136/205; 136/200; 427/58; 427/126.1; 427/535; 438/54; 136/201

(57) ABSTRACT

Provided is nano thermoelectric powder with a core-shell structure. Specifically, the nano thermoelectric powder of the core-shell structure of the present invention forms coating layer on the surface of nano powder prior to sintering of the nano powder. An advantage of some aspects of the present invention is that it provides thermoelectric elements having reduced thermal conductivity and enhanced thermoelectric efficiency without affecting electrical conductivity using the nano thermoelectric powder with the core-shell structure.

### TECHNICAL FIELD

The present disclosure relates to nano thermoelectric powder with a core-shell structure capable of enhancing thermoelectric efficiency, and thermoelectric elements using the same.

### BACKGROUND ART

In general, the thermoelectric material is an energy conversion material that produces electrical energy when giving temperature difference between both ends of the material, but produces temperature difference between both ends of the material when giving electrical energy to the material.

The efficiency of the thermoelectric material may be defined by the following equation that represents the dimensionless ZT value.

ZT=S²σT/K

(S: seeback coefficient, σ: electrical conductivity, κ: thermal conductivity)

The ZT value is proportional to the electrical conductivity and the seeback co-efficient, and is inversely proportional to the thermal conductivity.

Recently, to enhance the ZT value, many attempts to reduce the thermal conductivity have been performed.

The thermal conductivity κ include the thermal conductivity of electron and lattice, it is hard to control the thermal conductivity of electron due to the intrinsic properties of the material. However, since the thermal conductivity of lattice is a function affected by specific heat, mobility of phonon, and an average free path of phonon, the specific heat, the mobility of phonon, and the average free path of phonon are controlled to reduce the thermal conductivity.

Many groups adopts a type in which a simple nano structure is inserted into a bulk-type thermoelectric element and as a result, have focused only the increase in the scattering of the phonon affecting the thermal conductivity κ.

However, the type in which the simple nano structure is inserted into the bulk-type thermoelectric element also affects the reduction of the electrical conductivity σ, which is not enough to efficiently increase the ZT value.

Therefore, researches for reducing the thermal conductivity of the thermoelectric material are urgently required without reducing the electrical conductivity σ of the thermoelectric material.

### DISCLOSURE OF INVENTION

### Technical Problem

The present invention provides nano thermoelectric powder with a core-shell structure, including coating layers on a surface of the nano powder.

The present invention provides the thermoelectric elements obtained by sintering the nano thermoelectric powder with the core-shell structure.

### Solution to Problem

According to an embodiment of the present invention, there is provided a thermo-electric module including top and bottom insulating substrates formed with metal electrodes and facing each other, and a plurality of thermoelectric elements between the top and bottom insulating substrates, wherein the thermoelectric elements are the thermoelectric elements obtained by sintering the nano thermoelectric powder with the core-shell structure and are connected in series via the metal electrode formed by the media of the top and bottom insulating substrates.

According to another embodiment of the present invention, there is provided a method for manufacturing the nano thermoelectric powder with the core-shell structure of the present invention includes (a) manufacturing an ingot by inputting, melting and cooling basic materials into a furnace; (b) preparing nano powder by crushing and grinding the ingot; and (c) forming coating layers on a surface of the nano powder.

According to another embodiment of the present invention, there is provided a method for manufacturing the thermoelectric element of the present invention includes (a) manufacturing an ingot by inputting, melting and cooling basic materials into a furnace; (b) preparing the nano powder by crushing and grinding the ingot; (c) forming coating layers on a surface of the nano powder, and (d) sintering the nano thermo-electric powder with the core-shell structure manufactured in the forming of the coating layers.

The thermoelectric module of the present invention may be manufactured using the method alternately arranging and electrically connecting the thermoelectric elements on the top and bottom insulating substrates formed with the metal electrode, but is not limited thereto.

### Advantageous Effects of Invention

The present invention provides thermoelectric elements with the enhanced thermo-electric efficiency by forming a coating layer thinner than average free path of the phonon on the surface of the nano powder prior to sintering of the nano powder.

Since the average free path of the phonon has nano-scale, the coating layer having the nano-scale is formed on the surface of the nano powder.

The coating layer with the nano-scale formed on the surface of the nano powder does not affect the mobility of electron related to electrical conductivity, and increases only the scattering of the phonon, thereby providing the thermoelectric element having the reduced thermal conductivity without reducing the electrical conductivity.

### BRIEF DESCRIPTION OF DRAWINGS

The above and other aspects, features and advantages of certain exemplary embodiments of the present invention will be more apparent from the following description taken in conjunction with the accompanying drawings, in which:

FIG. 1 schematically shows a process of manufacturing thermoelectric elements according to the related art.

FIG. 2 schematically shows a process of manufacturing the thermoelectric elements of the present invention.

FIG. 3 schematically shows a process of manufacturing the thermoelectric elements by sintering nano thermoelectric powder with a core-shell structure synthesized according to an exemplary embodiment of the present invention.

### REFERENCE NUMERALS

A.: nano powder

B.: coating layer

C.: nano thermoelectric powder with a core-shell structure

D.: pellet-type thermoelectric element

### BEST MODE FOR CARRYING OUT THE INVENTION

Exemplary embodiments of the present invention will be described below in detail with reference to the accompanying drawings. Wherever possible, the same reference numerals will be used to refer to the same elements throughout the specification, and a duplicated description thereof will be omitted. It will be understood that although the terms “first”, “second”, etc. are used herein to describe various elements, these elements should not be limited by these terms. These terms are only used to distinguish one element from another element.

### Mode for the Invention

The present invention provides nano thermoelectric powder with a core-shell structure including coating layers on a surface of the nano powder, and may provide the thermoelectric elements having enhanced thermoelectric efficiency by the preparation of the nano thermoelectric powder with the core-shell structure.

The efficiency of the thermoelectric elements may be defined as the following equation that represents the dimensionless ZT value.

ZT=S²σT/K

(S: seeback coefficient, σ: electrical conductivity, κ: thermal conductivity)

The ZT value is proportional to the electrical conductivity and the seeback co-efficient, and is inversely proportional to the thermal conductivity.

Hereinafter, it is described in detail how the nano thermoelectric powder with the core-shell structure of the present invention may provide the thermoelectric elements having enhanced thermoelectric efficiency.

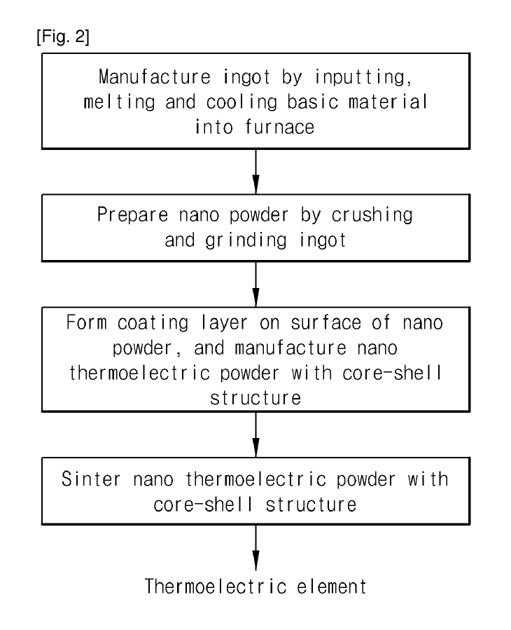

In FIG. 2, when manufacturing the thermoelectric elements by powder metallurgy, the nano powder is powder having a nano size obtained by crushing and grinding an ingot, and the nano powder is sintered to provide the thermoelectric elements .

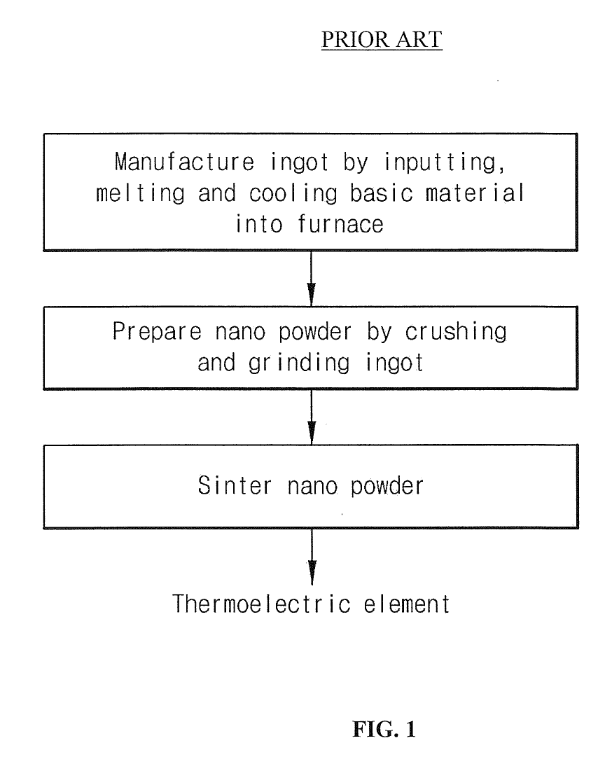

Unlike the process manufacturing prior thermoelectric elements of FIG. 1, as shown in FIG. 2, the present invention forms the coating layer on the surface of the nano powder by the sintering preprocessing process of the nano powder to provide the nano thermoelectric powder with the core-shell structure, and may provide the thermo-electric elements having reduced thermal conductivity and enhanced thermoelectric efficiency even without affecting the electrical conductivity σ due to the formed coating layer.

Specifically, to provide the thermoelectric elements having reduced thermal conductivity without affecting the electrical conductivity σ, the thickness of the coating layer formed on the surface of the nano powder has to be formed thinner than that of the average free path of the phonon, thereby allowing the scattering of the phonon to increase, lowering the thermal conductivity by the phonon and therefore, lowering the whole thermal conductivity κ. The present invention relates to the nano thermoelectric powder with the core-shell structure.

Here, the average free path of the phonon, which is the unique value of the material, depends on the material of the nano powder.

The material of the nano powder may use at least two types selected from the group composed of, for example, Bi, Te, Sb and Se, the average free path of the phonon of Bi2Te3 as an embodiment among them is roughly about 3 nm, and therefore, the thickness of the coating layer formed on the surface of the nano powder is preferably between 1 and 3.5 nm.

The coating layer with the nano-scale formed on the surface of the nano powder does not affect the mobility of the electron related to the electrical conductivity, and allows the scattering only of the phonon to increase, thereby providing the thermoelectric elements having reduced thermal conductivity even without reducing the electrical conductivity.

An average grain size of the nano powder of a core among the nano thermoelectric powder with the core-shell structure may be between 30 and 50 μm, but is not limited thereto.

The coating layer, that is, a shell among the nano thermoelectric powder with the core-shell structure consists of the same material as material composing the nano powder, or may be composed of other material.

The coating layer may be composed of at least one types selected from the group composed of Na, K, Rb, Bi, Te, Sb and Se, but is not limited thereto.

The present invention provides the thermoelectric elements having enhanced thermoelectric performance obtained by sintering the nano thermoelectric powder with the core-shell structure.

Further, the present invention provides the thermoelectric module including the thermoelectric elements.

The thermoelectric module including the thermoelectric elements may be implemented depending on the method adopting typically in the industry, but as non-restrictive example, includes top and bottom insulating substrates formed with the metal electrode and facing each other, and a plurality of thermoelectric elements s between the top and bottom insulating substrates wherein the thermoelectric elements are the thermoelectric elements obtained by sintering the nano thermoelectric powder with the core-shell structure of the present invention, and may be structure connected in serial by the media of the metal electrode of the top and bottom insulating substrates.

The method manufacturing the nano thermoelectric powder with the core-shell structure of the present invention includes (a) manufacturing an ingot by inputting, melting, and cooling the basic materials into a furnace; (b) preparing the nano powder by crushing and grinding the ingot; and (c) forming coating layers on the surface of the nano powder.

The manufacturing the ingot may be performed depending on the ordinary method in the art. For example, The manufacturing the ingot may be manufactured by inputting, melting, and cooling the basic materials into the furnace.

The base material may use at least two selected from the group composed of Bi, Te, Sb and Se, but is not limited thereto.

The preparing the nano powder crushes and grinds the ingot manufactured in the manufacturing of the ingot into the nano powder depending on the ordinary method in the art.

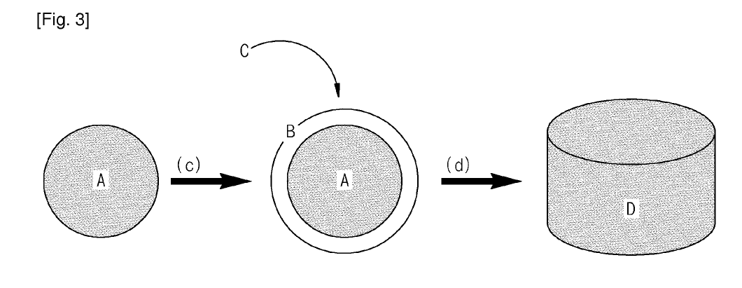

In FIG. 3, the forming of coating layers forms the coating layer B on the surface of the nano powder A, wherein the coating layers may be formed by an Atomic Layer Deposition (ALD) method or a Hydrothermal Deposition method and is not limited thereto.

When forming the coating layer on the surface of the nano powder by the Atomic Layer Deposition (ALD) method, at least one precursor selected from the group composed of BiMe3, TeMe2, SbMe3, SeMe2, BiC13, TeC12, SbC13, SeC12, [Bi(SiMe3)3], [Te(SiMe3)2], [Sb(SiMe3)3] and [Se(SiMe3)2] may be used.

Further, when forming the coating layer on the surface of the nano powder by the Hydrothermal Deposition method, at least one precursor selected from the group composed of NaOH, KOH, RbOH, NaBH4, KBH4 and RbBH4 may be used.

The nano thermoelectric powder with the core-shell structure of the present invention may form the coating layer thinner than the average free path of phonon on the surface of the nano powder by the Atomic Layer Deposition (ALD) method or the Hydrothermal Deposition method, and the like.

The nano thermoelectric powder with the core-shell structure of the present invention is manufactured through the following (a) to (c) processes, and the thermoelectric elements may be manufactured through the following (d) process.

(a) manufacturing an ingot by inputting, melting, and cooling basic materials into a furnacel; (b) preparing the nano powder by crushing and grinding the ingot; (c) forming coating layers on the surface of the nano powder, and (d) sintering the nano thermoelectric powder with the core-shell structure manufactured in the forming of the coating layer.

In FIG. 3, the sintering of the nano thermoelectric powder sinters the nano thermoelectric powder C with the core-shell structure in which the coating layer B is formed on the surface of the nano powder A of the present invention to produce a pellet-type thermoelectric element D, and the sintering is performed depending on the method on the ordinary method in the art, for example, a Hot Press method and a Spark Plasma Sintering method.

In the thermoelectric elements manufactured through the (a) to (d) processes, the coating layer, that is, shells of the nano thermoelectric powder with the core-shell structure does not affect the mobility of electron related to the electrical conductivity, and increases only the scattering of phonon, thereby reducing the thermal conductivity while maintaining the electrical conductivity and therefore, enhancing the thermoelectric performance.

The present invention provides the thermoelectric module including the thermoelectric elements with very enhanced thermoelectric performance.

The thermoelectric module may be manufactured depending on the ordinary method in the art. For example, the thermocouple module may be manufactured by alternately arranging and electrically connecting the thermoelectric elements of the present invention on the top and bottom insulating substrates on which the metal electrodes are formed.

While the invention has been shown and described with reference to exemplary embodiments thereof, it will be understood by those skilled in the art that various changes in form and details may be made therein without departing from the spirit and scope of the invention as defined by the appended claims. Therefore, the scope of the invention is defined not by the detailed description of the invention but by the appended claims, and all differences within the scope will be construed as being included in the present invention.

1. A nano thermoelectric powder with a core-shell structure comprising a coating layer on a surface of the nano powder.

2. The nano thermoelectric powder with the core-shell structure of claim 1, wherein a thickness of the coating layer is thinner than that of a average free path of phonon.

3. The nano thermoelectric powder with the core-shell structure of claim 1, wherein the thickness of the coating layer is between 1 and 3.5 nm.

4. The nano thermoelectric powder with the core-shell structure of claim 1, wherein the nano powder is at least two powders selected from the group composed of Bi, Te, Sb and Se.

5. The nano thermoelectric powder with the core-shell structure of claim 1, wherein an average grain size of the nano powder is between 30 and 50 μm.

6. The nano thermoelectric powder with the core-shell structure of claim 1, wherein the coating layer consists of the same material as a material composing the nano powder.

7. The nano thermoelectric powder with the core-shell structure of claim 1, wherein the coating layer consists of a material different from the material composing the nano powder.

8. The nano thermoelectric powder with the core-shell structure of claim 1, wherein the coating layer is composed of at least one or two selected from the group composed of Na, K, Rb, Bi, Te, Sb and Se.

9. Thermoelectric elements obtained by sintering the nano thermoelectric powder with the core-shell structure of claim 1.

10. A thermoelectric module, comprising top and bottom insulating substrates formed with metal electrodes and facing each other, and a plurality of thermoelectric elements between the top and bottom insulating substrates, wherein the thermoelectric elements are the thermoelectric elements of claim 9, and the thermoelectric elements s are connected in series via the metal electrode formed on the media of the top and bottom insulating substrates.

11. The method manufacturing nano thermoelectric powder with a core-shell structure, comprising (a) manufacturing an ingot by inputting, melting and cooling basic materials into a furnace; (b) preparing the nano powder by crushing and grinding the ingot; and (c) forming coating layers on the surface of the nano powder.

12. The method manufacturing the nano thermoelectric powder with the core-shell structure of claim 11, wherein the basic materials in the manufacturing of an ingot uses at least two selected from the group consisted of Bi, Te, Sb and Se.

13. The method manufacturing the nano thermoelectric powder with a core-shell structure of claim 11, wherein the coating layer in the forming of coating layers is formed by ALD(Atomic Layer Deposition) method; or Hydrothermal Deposition method.

14. The method manufacturing the nano thermoelectric powder with the core-shell structure of claim 13, wherein the coating layer in the forming of coating layers is formed by the ALD(Atomic Layer Deposition) method using at least one precursor selected from the group composed of BiMe₃, TeMe₂, SbMe₃, SeMe₂, BiCl₃, TeCl₂, SbCl₃, SeCl₂, [Bi(SiMe₃)₃], [Te(SiMe₃)₂], [Sb(SiMe₃)₃] and [Se(SiMe₃)₂].

15. The method manufacturing the nano thermoelectric powder with the core-shell structure of claim 13, wherein the coating layer in the forming of coating layers is formed by Hydrothermal Deposition method using at least one precursor selected from the group consisted of NaOH, KOH, RbOH, NaBH₄, KBH₄ and RbBH₄.

16. The method manufacturing the thermoelectric elements, comprising (a) manufacturing an ingot by inputing, melting and cooling the basic materials into the furnace; (b) preparing the nano powder by crushing and grinding the ingot; (c) forming coating layers on the surface of the nano powder, and (d) sintering the nano thermoelectric powder with the core-shell structure manufactured in the forming of coating layers.

17. The method manufacturing the thermoelectric elements of claim 16, wherein the sintering of the nano thermoelectric powder is performed by a Hot Press method and a Spark Plasma Sintering method.

18. The method manufacturing the thermoelectric module alternately arranging and electrically connecting thermoelectric elements manufactured of claim 16 on the top and bottom insulating substrates formed with the metal electrode.
